(19) United States
(12) Patent Application Publication
(10) Pub. No.: US 2002/0056876 A1
(43) Pub. Date: May 16, 2002

(54) SEMICONDUCTOR DEVICE

(76) Inventors: HANS U. SCHROEDER, ZURICH (CH); PAUL G.M. GRADENWITZ, ZURICH (CH)

Correspondence Address: CORPORATE PATENT COUNSEL, U S PHILIPS CORPORATION, 580 WHITE PLAINS ROAD, TARRYTOWN, NY, 10591

(21) Appl. No.: 09/389,826

(22) Filed: Sep. 3, 1999

(30) Foreign Application Priority Data
Sep. 3, 1998 (EP) 982202948.0

(51) Int. Cl. H01L 23/62

(52) U.S. Cl. 257/355

(57) ABSTRACT

For the protection of an integrated circuit against ESD, it is known to use a Silicon-Controlled Rectifier (SCR), provided with a gated diode or MOS transistor at the periphery of the well to obtain a low trigger voltage. In accordance with the invention, the said gated diode or MOS transistor, located between the anode and the cathode of the SCR, is provided only along a part of the periphery of the SCR, a part of the SCR thus being free from the said gated diode. As a result of this structure, the holding voltage of the SCR is reduced considerably, leading to an important decrease of the dissipation during the ESD event.

### DESCRIPTION

The invention relates to a semiconductor device having a semiconductor body which on a surface comprises an integrated circuit containing protection means for protection against electrostatic discharge (ESD), the means being a compound element of an SCR and a gated diode, the protection means being provided in a surface area of a first conductivity type having a well of a second, opposite, conductivity type in which area a surface zone of the first conductivity type is formed forming one of the anode and cathode zones of the SCR element, and the surface area having a surface zone of the second conductivity type, further denoted as first zone, situated remote from the well and forming the other anode and cathode area of the SCR element, the gated diode containing a gate insulated from the surface of the semiconductor body and a highly-doped second conductivity type surface zone aligned to this gate further denoted as second zone, which aligned surface zone partly overlaps the well of the second conductivity type. Such a device is known, for example, from the article “A Low-Voltage Triggering SCR for On-Chip ESD Protection at Output and Input Pads” by A. Chatterjee et al., published in IEEE Electron Device Letters, vol. 12, no. 1, January 1991, pp. 21 and 22.

An SCR element (Silicon-Controlled Rectifier) is a four-layer npnp structure with connections on the outer n-layer and p-layer. As is known, the resistance of such an element in the one state is very high, so that no or substantially no current flows through the element; in the other state the resistance is very low, so that the element may carry a large current. The element changes from the one, non-conductive, state to the other state where the voltage between the connections reaches a certain value, the so-called trigger voltage. Beyond this point of the I-V characteristic, the voltage between the connections drops to a low value, the so-called holding voltage, and the I-V curve becomes very steep. When utilizing an SCR element as a protection of a CMOS circuit or a BICMOS circuit against ESD damage, it is important for the trigger voltage to be lower than the lowest voltage on the I/O pads at which damage may occur in the circuit. Generally, the trigger voltage is determined by the breakdown voltage of a pn-transition. In a standard CMOS process, the breakdown voltage of the pn-junction lies between the n well and the p-type surface area in the neighborhood of 40 V, which is much too high for ESD protection. The breakdown voltage of the pn-junction of the source/drain zone of the n-channel MOS transistors is about 10 V. By providing a gated diode along the edge of the well, for example, in the form of a MOS transistor, a trigger voltage of the desired value may be obtained. The transistor source or drain zone overlapping the well forms a gated diode triggering the SCR element, the other zone of the transistor forming the cathode of the SCR element in the known device.

The holding voltage should generally be larger than the supply voltage. In order to keep the dissipation in the protection lowest possible, a low holding voltage is desired. In practice it has turned out that in most standard processes the holding voltage lies above 6 V. However, often a lower holding voltage is desired, more particularly in low-power applications where the supply voltage is 3.3 V or less.

Therefore, it is an object of the invention to provide an ESD protection which has not only a low trigger voltage but also a low holding voltage. In addition, the invention is based, for example, on the recognition that in the known device the transistor zone overlapping the well shields the anode from load carriers which are injected by the cathode. The invention is further based on the recognition that the holding voltage, which generally increases when the distance between anode and cathode increases, is adversely affected by the presence of the transistor between anode and cathode.

A semiconductor device according to the invention of the type described in the opening paragraph is therefore characterized in that the said second zone stretches out only along a part of the periphery of the well, whereas the first zone is provided along at least another part of this periphery of the well which is free from the said second zone. This configuration achieves that the anode and the cathode, in effect, are not shielded from each other by the gated diode, so that the load carriers injected by the cathode can reach the anode more easily, which results in a considerably lower holding voltage than in known devices.

A preferred embodiment of a device according to the invention is characterized in that the gate of the gated diode substantially stretches out only along that part of the periphery of the well along which also the said second zone of the second conductivity type stretches out. This embodiment is advantageous, for example, in that the leakage current is relatively small as a result of the limited gate length. A further embodiment of a device according to the invention is characterized in that the gated diode is arranged in the form of a MOS transistor which has a further surface zone of the second conductivity type, deposited in the surface area of the first conductivity type, the said second zone forming one of the source/drain zones of the transistor and the said further surface zone forming the other one of the source/drain zones of the transistor, the said first zone of the second conductivity type being situated at a shorter lateral distance from the surface zone of the first conductivity type provided in the well than the said further surface zone. In practice it turns out that the holding voltage more or less linearly changes with the distance from anode to cathode. In this embodiment, the option is used of making this distance very small in a device according to the invention, that is, essentially smaller than the distance between the anode and the source of the transistor.

These and other aspects of the invention will be apparent from and elucidated with reference to the embodiments described hereinafter.

In the drawings:

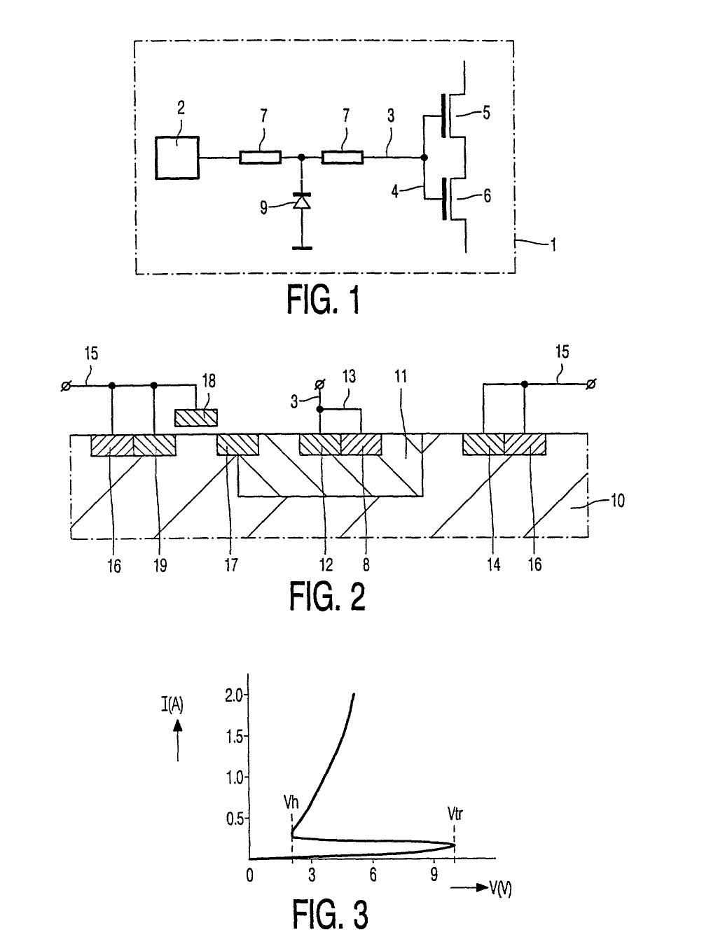

FIG. 1 shows a part of an integrated circuit having an input protection against electrostatic discharge;

FIG. 2 shows a cross-section of an ESD protection according to the invention;

FIG. 3 shows a current/voltage characteristic of the ESD protection of FIG. 2;

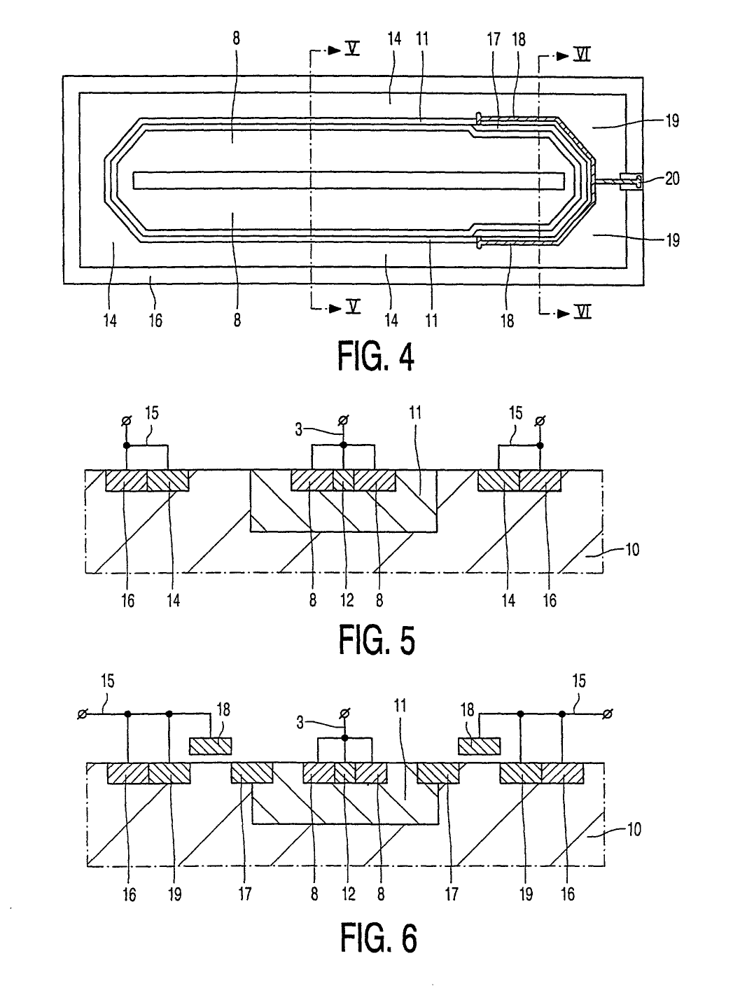

FIG. 4 shows the layout of a second embodiment of an ESD protection according to the invention;

FIG. 5 shows a cross-section of this second embodiment along the line V-V; and

FIG. 6 shows a cross-section of this embodiment along the line VI-VI in FIG. 4.

FIG. 1 shows in a diagram the input part of an integrated circuit 1 having an input path 2 which is connected by wire bonding (not shown) to an input pin of a customary envelope (not shown either). The input path 2 is connected by a conductor 3 to an input port 4 of the circuit, which input port comprises, for example, a p-channel transistor 5, and an n-channel transistor 6, the transistor gates being connected to the conductor 3. The spreading of the resistance in the conductor 3 is represented diagrammatically by the resistors 7. For protecting the circuit against damage owing to electrostatic discharge (ESD), caused, for example, by contact between the input pin of the envelope and a human body, a protection element 9 is inserted whose one side is connected to the conductor 3 and whose other side is connected to a reference voltage, for example, ground. The element 9 shown in the Figure as a diode for simplicity, is formed by a four-layer structure of alternating conductivity type, therefore, of a pnpn structure often referred to as SCR (Silicon-Controlled Rectifier). The current/voltage characteristic shows a first region (see FIG. 3) between 0 volts and Vₜᵣ volts in which the SCR element conducts no or substantially no current. This is the state in which the element is under normal conditions. In the case of the trigger voltage Vₜᵣ, the element changes to a conductive state in which the voltage drops to a low value Vₕ, the holding voltage, and the resistance of the SCR element becomes very low. For effectively protecting the circuit against ESD, it is necessary for Vₜᵣ to be lower than the voltage at which damage occurs. This means that for current CMOS processes Vₜᵣ is to be equal or substantially equal to 10 V. For a rapid discharge in the case of ESD and for keeping the heat development in the protection itself lowest possible, a lowest possible Vₕ is desired (be it higher than the supply voltage). Since the supply voltage for the ever diminishing dimensions in silicon technology shows a tendency to ever decreasing values, an SCR protection with a low Vₕ is ever more desired.

FIG. 2 shows in a cross-sectional view a protection element 9 according to the invention, which element also has a low holding voltage Vₕ when there is a suitable trigger voltage. A semiconductor body of, for example, silicon is started from, of which FIG. 2 only shows the surface area 10 containing the protection element 9. In the specific embodiment to be described here, the surface area is of the p type. However, it will be plainly evident to the expert that also embodiments which have reversed conductivity types of the various areas and zones are possible. In the surface area 10 is provided an n-type well 11, for example, during the n-well implantation for the p-channel transistors elsewhere in the semiconductor body. In the well 11 there is a p-type surface zone 12 which forms the anode of the SCR element 9 and is connected to the input path 2 via the conductor 3. By means of the contact 13 shown only diagrammatically in FIG. 2, and the highly doped contact zone 12, the anode 8 is also connected to the well 11. The p-type surface area 10 further includes an n-type surface zone 14 which lies remote from the well 11 and forms the cathode of the SCR element. By means of the conductor 15 shown diagrammatically, the cathode 14 is connected to a reference voltage, for example ground. The p-type surface area 10 is in this example also connected to ground by the conductor 15 and the highly doped p-type surface zone 16. For obtaining a sufficiently low trigger voltage, the device has a gated diode structure comprising a highly doped n-type surface zone 17 provided in the p-type surface area 10 and a gate 18 electrically insulated from the surface area 10 aligned relative to the zone 17. The zone 17 is electrically connected to the well 11 by having the zone 17 adjoin the well 11 or, as is shown in the drawing, by having it overlap the well 11. In the embodiment shown in FIG. 2 the gate 18 is connected by a conductor 15 to the substrate 10 and to the low reference voltage. In another embodiment, gate 8 is coupled to ground via a resistor and via a diode or a capacitor to zone 17. This configuration provides that the trigger voltage of the protection is not determined by the (high) breakdown voltage of the pn transition between the well 11 and the surface area 10, but by the gated diode 17, 18. The gated diode may be manufactured simultaneously with the n-channel transistors of the circuit so that, with the current standard CMOS processes, a breakdown voltage equal to or substantially equal to 10 V may be achieved.

In principle, the gated diode having the zone 17 and the gate 18 is sufficient. In the example shown, on the side of the gate 18, opposite zone 17, a further highly-doped n-type zone 19 is provided in the p-type surface area 10, so that the gated diode has the structure of a MOS transistor. The zone 19 is also connected to the low reference voltage and to the substrate 10 and, as a result, also operates as a cathode of the SCR element, be it in less efficient manner than the n-type zone 14.

FIG. 4 shows a plan view of an ESD protection according to the invention having another layout compared with the previous example. Cross-sections of the device along the lines V-V and VI-VI are represented in FIG. 5, FIG. 6 respectively. The n-type well 18 is arranged in the form of a longitudinal zone having two ends on the left and right-hand side of the drawing. The anode 8 is formed by a longitudinal p-type zone in the n-well 11 which well has in its center an opening at the position of which a highly doped n-type zone 12 is provided which forms a contact area for the well 11. The gated diode is solely provided on the righthand end and comprises the insulated gate 18 and the highly doped n-type zone 17 which partly overlaps the well 11. In this example, the gated diode is also arranged as a MOS transistor having a further n-type zone 19. The cathode of the SCR, formed by the highly doped n-type zone 14 is provided along the part of the periphery of the well 11 that is free from the gate 18 at a minor distance from the anode 8. The ratio between the two parts of the periphery may be chosen with relatively large freedom depending on the circumstances. FIG. 4 shows an embodiment in which the gated diode takes up only a relatively small part of the periphery of the SCR and thus has very little influence on the holding voltage Vₕ and on the current-conveying power of the SCR. At the position of the contact 20, the gate 18 is connected to the p-type substrate 10 and to the n-type cathode 14 which, together with the further zone 19, forms a coherent area. Needless to observe that, if so desired, the gate may also be connected to a junction in the circuit to another, suitable, voltage.

It will be evident that the invention is not restricted to the examples described above, but that within the framework of the invention a great many variations are possible to the expert. For example, a plurality of parallel-arranged SCR elements as shown in FIG. 4 may be used to increase the current-conveying power. In the examples described, the conductivity types may be reversed too, needless to observe that voltages to be applied are to be adapted and functions of anode and cathode are exchanged. The protection element may be used in protection circuitries, differing from the circuitry shown in FIG. 1.

1. A semiconductor device having a semiconductor body which on a surface comprises an integrated circuit containing protection means for protection against electrostatic discharge (ESD), the means being a compound element of an SCR and a gated diode, the protection means being provided in a surface area of a first conductivity type having a well of a second, opposite, conductivity type in which area a surface zone of the first conductivity type is formed forming one of the anode and cathode zones of the SCR element, and the surface area having a surface zone of the second conductivity type, further denoted as first zone, situated remote from the well and forming the other anode and cathode area of the SCR element, the gated diode containing a gate insulated from the surface of the semiconductor body and a highly-doped second conductivity type surface zone aligned to this gate further denoted as second zone, which aligned surface zone partly overlaps the well of the second conductivity type, characterized in that the said second zone stretches out only along a part of the periphery of the well, whereas the first zone is provided along at least another part of this periphery of the well which is free from the said second zone.

2. A semiconductor device as claimed in claim 1, characterized in that the gate of the gated diode substantially stretches out only along that part of the periphery of the well along which also the said second zone of the second conductivity type stretches out.

3. A semiconductor device as claimed in claim 2, characterized in that the gated diode is arranged in the form of a MOS transistor which has a further surface zone of the second conductivity type, deposited in the surface area of the first conductivity type, the said second zone forming one of the source/drain zones of the transistor and the said further surface zone forming the other one of the source/drain zones of the transistor, the said first zone of the second conductivity type being situated at a shorter lateral distance from the surface zone of the first conductivity type provided in the well than the said further surface zone.

4. A semiconductor device as claimed in claim 3, characterized in that the said further zone of the second conductivity type and the said first zone of the second conductivity type form a coherent zone of the second conductivity type.

5. A semiconductor device as claimed in one of the preceding claims, characterized in that the first and the second conductivity type are the p-conductivity type and n-conductivity type respectively, the said first zone forming the cathode of the SCR element and the first conductivity type zone arranged in the well forming the anode of the SCR element.
